(19) United States
(12) Patent Application Publication
(10) Pub. No.: US 2008/0142836 A1
(43) Pub. Date: Jun. 19, 2008

(54) Method for growth of alloy layers with compositional curvature in a semiconductor device

(76) Inventor: Darwin Gene Enicks, Colorado Springs, CO (US)

Correspondence Address: SAWYER LAW GROUP LLP, P O BOX 51418, PALO ALTO, CA, 94303, US

(21) Appl. No.: 11/639,464

(22) Filed: Dec. 15, 2006

(51) Int. Cl. H01L 29/737; H01L 21/205

(52) U.S. Cl. 257/190; 438/478; 257/E29.193; 257/E21.103; 257/197

(57) ABSTRACT

A method and system for providing an alloy layer in a semiconductor device are described. The method and system ramping a first gas including a first constituent of the alloy layer from a first level to a second level different from the first level while the alloy layer is grown. The method and system also include ramping a second gas including a second constituent of the alloy layer from a third level to a fourth level different from the third level while the alloy layer is grown. In one aspect, the alloy layer includes silicon and germanium. In this aspect, the first gas includes silicon, while the second gas includes germanium.

### FIELD OF THE INVENTION

The present invention relates to semiconductor processing, and more particularly to a method and system for providing alloy layers, such as SiGe layers, in the semiconductor device.

### BACKGROUND OF THE INVENTION

SiGe alloy layers are applicable to a wide range of device technologies made possible by advantages provided by the addition of Ge to the Si lattice. For example, a conventional SiGe heterojunction bipolar transistor (HBT) has significant advantages over a silicon bipolar junction transistor (BJT) in gain, frequency response, noise parameters while retaining the ability to be readily integrated with CMOS at relatively low cost. The silicon compatible conventional SiGe HBT provides a low cost, high speed, low power solution that is quickly replacing other compound semiconductor devices.

FIG. 1 depicts the filmstack of a conventional SiGe device 10 formed on a substrate 11. The conventional SiGe device 10 includes a conventional collector region 12, a conventional compound base region 16, and a conventional emitter region 20. The conventional SiGe device 10 may also include a conventional spacer (or seed) layer 14 and a conventional capping layer 18. In the conventional SiGe device 10, the conventional spacer layer 14 is typically an elemental semiconductor, such as silicon. The conventional base region 16 is typically formed from a compound semiconductor, such as SiGe or SiGeC (SiGe doped with C) (collectively hereinafter SiGe/SiGeC). The conventional capping layer 18 is typically an elemental semiconductor, such as silicon. The conventional emitter layer 18 is typically polysilicon. One of ordinary in the art will recognize that other materials of the poly-, mono-, and/or amorphous construction will also work well for the emitter layer, such as poly-SiGe or amorphous silicon, to name a few. The conventional SiGe device 10 may either be npn or pnp, depending on the device application. Use of the conventional SiGe/SiGeC layer for the conventional compound base region 16 results in a base-emitter heterojunction. Because SiGe has a lower energy bandgap than silicon, the base-emitter heterojunction results in a bandgap offset between the conventional compound base 16 and the conventional emitter 20. In order to obtain the desired characteristics of a SiGe HBT, or other SiGe devices, the bandgap of the device is engineered through the use of dopant profiles.

FIG. 2 depicts the energy band structure 30 of an npn SiGe device, such as the SiGe device 10, in conjunction with the graded profiles of Ge and B. The concentration of Ge is generally determined by the Ge provided during growth of the SiGe layer, as discussed below. The B is typically added in-situ during the SiGe layer growth. Thus, the concentrations shown in FIG. 2 are present after a SiGe alloy has been grown. In addition, the base, emitter, and collector regions shown in the energy band structure 30 correspond to the layers depicted in the device 10 of FIG. 1.

Referring back to FIG. 2, in the conventional SiGe device 10, the Ge profile 32 is typically linear in nature. Thus, the concentration of Ge in the device varies linearly with the depth of the layer. The B profile 34 is depicted as having a square profile. However, other profiles, such as Gaussian profiles, may also be used. Where the profiles 32 and 34 indicate that the concentrations of Ge and B are zero, the device includes silicon. Also depicted in FIG. 2 are the energy band gap offset at the base-emitter metallurgical junction (ΔEG(0)) and the bandgap grading across the neutral base region (ΔEG(grade)). ΔEG(grade may be determined by ΔEG(x=W_{b})−ΔEG(0), where W_{b} is the width of the base region as defined by the active boron profile. In addition, the built-in carrier drift E_{drift} is ΔEG(grade)/W_{b}.

The values ΔEG(0) and ΔEG(grade) are generally important components to the SiGe device performance. Each of these bandgap effects is induced by the incorporation of Ge into the silicon lattice. Current density (J_{c}) is exponentially dependent on the bandgap offset at the base-emitter heterojunction (ΔEG(0)) and linearly dependent on the Ge grade or (ΔEG(grade)). In other words:

J_{c}αexp[ΔEG(0)]*(ΔEG(grade))

Consequently, engineering a successful SiGe device typically includes providing the desired ΔEG(0) and ΔEG(grade). In addition, it may be noted that differing profiles may have the same bandgap energy offsets. In particular, FIG. 3 depicts three profiles, convex 36, linear 38, and concave 40 which have the same ΔEG(0) and ΔEG(grade). Consequently, all three profiles 36, 38, and 40 may result in a device having similar properties to those depicted in FIG. 2.

Referring back to FIG. 2, the conventional SiGe device 10 may have a relatively narrow profile 34 for B. The diffusion of B in SiGe is typically significantly lower than the diffusion of B in Si. Consequently, the B profile 34 and thus the conventional base region 16 may be made very narrow. Similarly, in SiGe MOSFETS (not shown), ultra-shallow p-type junctions may be realized due to the reduced B diffusion in SiGe. Thus, the bandgap engineering, low diffusivity of B, and other properties make SiGe alloys, in which Ge is incorporated into the Si lattice, desirable for many devices.

Another property of SiGe layers is that such layers are typically strained. Because there is a lattice mismatch between Si and Ge, incorporation of Ge into the Si lattice in the formation of an SiGe layer results in strain along the <100> crystalline face. This results in properties that may be beneficial. For example, a SiGe layer may exhibit enhanced hole mobility due to the strain induced in SiGe formation. This is true, for example, in the base of an NPN SiGe HBT. The SiGe layer might also used to provide enhanced electron mobility in other layers. For example, a strained silicon film grown on a relaxed SiGe buffer layer may have enhanced electron mobility. Such a strained silicon film may, for example, be used in field effect transistor devices. The strain in a SiGe layer is proportional to the total integrated Ge within the SiGe layer. Thus, for the Ge profiles 36, 38, and 40 depicted in FIG. 3, the concave profile 40 has the lowest strain, the linear profile 38 has the next highest strain, and the convex profile 36 has the highest strain.

Although strained SiGe is useful, one of ordinary skill in the art will recognize that downstream thermal processing of a SiGe device may adversely affect performance, reliability, and manufacturability of the device. If a SiGe film has greater than a particular amount of Ge, relaxation of the film may occur. FIG. 4 depicts stable region 40, metastable region 42, and relaxed region 44 of a SiGe layer. The line 46 depicting the transition between the stable region 40 and metastable region 42 is known as the critical thickness for the SiGe layer. A SiGe layer having a greater thickness than the critical thickness for that concentration may relax, for example during to downstream thermal processing. Consequently, for thicker SiGe films and/or for SiGe films having a greater concentration of Ge, downstream thermal processing may adversely affect performance.

FIG. 5 depicts a conventional method 50 for growing a SiGe alloy layer, for example for use in a SiGe HBT device. The method 50 can generally be described as linearly ramping a single flow rate. In the method 50, the flow rate for either SiH₄ or GeH₄ gas is ramped. The SiGe layer is grown on an underlying silicon layer generally using SiH₄ and GeH₄. The flow rate of one of SiH₄ and GeH₄ is set at a constant value, via step 52. The initial flow rate for the other of GeH₄ or SiH₄ is set, via step 54. Growth of the film is carried out as the flow rate for GeH₄ or SiH₄ gas is ramped, via step 56. Typically, the flow rate is linearly ramped in step 56.

Although the method 50 functions, one of ordinary skill in the art will recognize that there are drawbacks. If the GeH₄ is linearly ramped in step 56, the resulting Ge profile is convex. As mentioned above, current devices typically use a linear Ge profile. For this reason, a convex profile is undesirable. Moreover, a convex profile contains more Ge at a particular thickness than a linear profile. Consequently, a SiGe layer having a convex profile has a lower value of critical thickness for a given total amount of integrated Ge. Stated differently, a SiGe layer that has a convex Ge profile may be more prone to be adversely affected by both growth conditions and downstream thermal processing. Consequently, linearly ramping the GeH₄ flow rate while leaving the SiH₄ flow rate constant is undesirable. Alternatively, the SiH₄ flow rate could be linearly ramped from low to high in step 56 while the GeH₄ flow rate is held constant. A concave Ge profile would result. However, as mentioned above, current devices typically use a linear Ge profile. Furthermore, the constant flow rate for the Ge in such a scheme would be high enough to achieve the desired Ge concentration at the base-collector side of the SiGe device 10. Such a high flow rate may not allow the Ge profile to have sufficiently low concentrations at the BE side of the device 10. As a result, the built-in carrier drift field across the base region, E_{drift}, may be severely limited by this method.

Consequently, FIG. 6 depicts another conventional method 60 for growing a SiGe alloy layer, for example for use in a SiGe HBT device. The method 60 can generally be described as step-wise ramping a single flow rate. In the method 60, the flow rate for GeH₄ is ramped. The SiGe layer is grown on an underlying silicon layer generally using SiH₄ and GeH₄. The flow rate of SiH₄ is set at a constant value, via step 62. The GeH₄ flow rate is set at a high value, via step 64. Growth of the film is carried out as the flow rate for GeH₄ is ramped to a lower value using a predetermined recipe of step times and flow rates, via step 66. Thus, in step GeH₄ flow rate is set at differing values for differing times. The resultant may be the linear profile 32 depicted in FIG. 2.

Although the method 60 functions in achieving the currently standard linear Ge profile 32, one of ordinary skill in the art will recognize that the method typically requires numerous process steps and is, therefore, very complex. Consequently, there is an increased probability of mistakes resulting in a lower yield, as well as increased time to fabricate the SiGe layer and, therefore, the device of which the SiGe layer is a part.

Consequently, FIG. 7 depicts another conventional method 70 for growing a SiGe alloy layer, for example for use in a SiGe HBT device. The method 70 can generally be described as nonlinearly ramping a single flow rate. In the method 70, the flow rate for GeH₄ is ramped. The SiGe layer is grown on an underlying silicon layer generally using SiH₄ and GeH₄. An engineer determines the GeH₄ flow rate versus percentage Ge for a variety of flow rates, via step 72. Based on this determination, software provides a recipe for nonlinearly ramping the flow rate to achieve the desired linear profile 32 of Ge, via step 74. The flow rate of SiH₄ is set at a constant value, via step 76. The GeH₄ flow rate is set at a high value, via step 78. Growth of the film is carried out as the flow rate for GeH₄ is nonlinearly ramped to a lower value in accordance with the recipe provided by the software, via step 78.

Although the method 70 functions, one of ordinary skill in the art will recognize that the method is complex. More importantly, the method 70 is largely inflexible. Moreover, although the linear Ge profile 32 achieved is what the conventional SiGe device 10 utilizes, other profiles may be more desirable. The method 70 may not be extensible to achieve such other profiles.

Accordingly, what is needed is a method and system for improving manufacturability and performance of the conventional HBT device 10. The present invention addresses such a need.

### BRIEF SUMMARY OF THE INVENTION

A method and system for providing an alloy layer in a semiconductor device are described. The method and system ramping a first gas including a first constituent of the alloy layer from a first level to a second level different from the first level while the alloy layer is grown. The method and system also include ramping a second gas including a second constituent of the alloy layer from a third level to a fourth level different from the third level while the alloy layer is grown. In one aspect, the alloy layer includes silicon and germanium. In this aspect, the first gas includes silicon, while the second gas includes germanium.

According to the method and system disclosed herein, desired profiles of the constituents of the alloy may be provided. Thus, the desired energy band offsets across the layer and/or at the boundaries of the layer, the desired dopant diffusion characteristics within the layer, and/or the desired strain gradients across the layer may be achieved. For example, a convex germanium profile may be achieved. As a result, a SiGe layer may have a stable thickness greater than the critical thickness of a box shaped SiGe layer and is therefore less susceptible to film relaxation. Consequently, processing and device variations may be reduced and device performance improved.

### BRIEF DESCRIPTION OF SEVERAL VIEWS OF THE DRAWINGS

FIG. 1 is a diagram of a conventional heterojunction bipolar transistor device.

FIG. 2 depicts the energy band structure of a conventional npn HBT device in a forward active mode.

FIG. 3 depicts the energy band offsets for various Ge profiles.

FIG. 4 depicts stable, metastable, and relaxed region of a SiGe alloy.

FIG. 5 depicts a conventional method for forming a SiGe layer.

FIG. 6 depicts another conventional method for forming a SiGe layer.

FIG. 7 depicts another conventional method for forming a SiGe layer.

FIG. 8 is a flow chart depicting one embodiment of a method for providing an alloy layer having the desired profile in a semiconductor device.

FIG. 9 is a flow chart depicting one embodiment of a method for providing a SiGe layer having the desired Ge profile in a semiconductor device.

FIG. 10 is a flow chart depicting another embodiment of a method for providing a SiGe layer having the desired Ge profile in a semiconductor device.

FIG. 11 depicts one embodiment of a Ge profile achieved using one embodiment of the method.

FIG. 12 depicts another embodiment of a Ge profile achieved using one embodiment of the method.

FIG. 13 depicts another embodiment of a Ge profile achieved using one embodiment of the method.

FIG. 14 depicts another embodiment of a Ge profile achieved using one embodiment of the method.

FIG. 15 depicts one embodiment of a HBT device in achieved using one embodiment of the method.

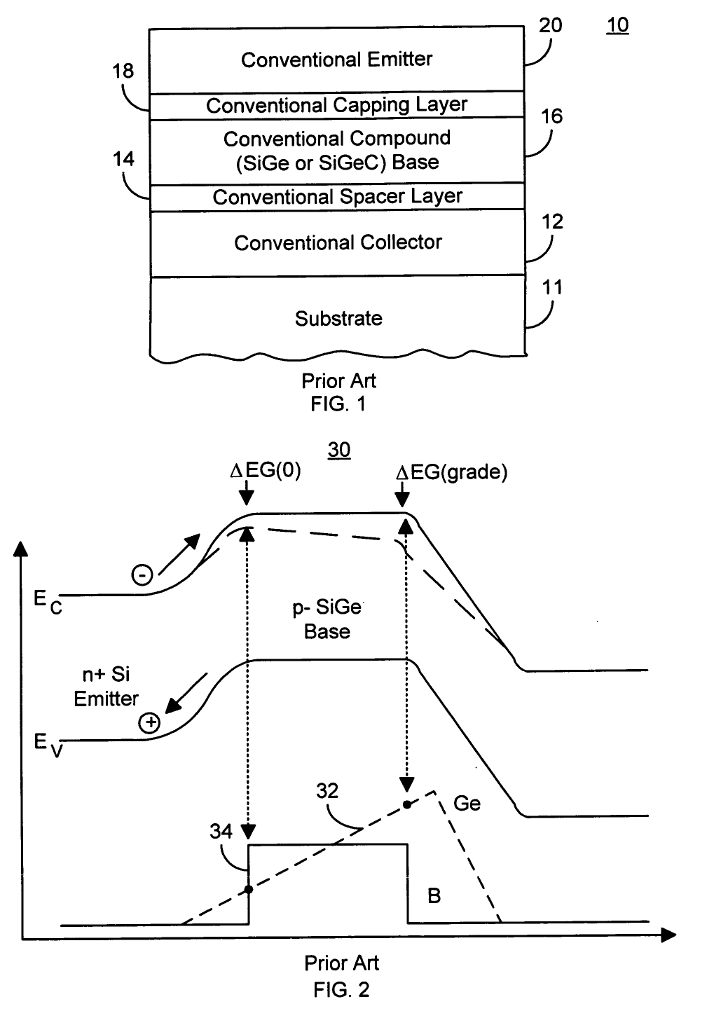

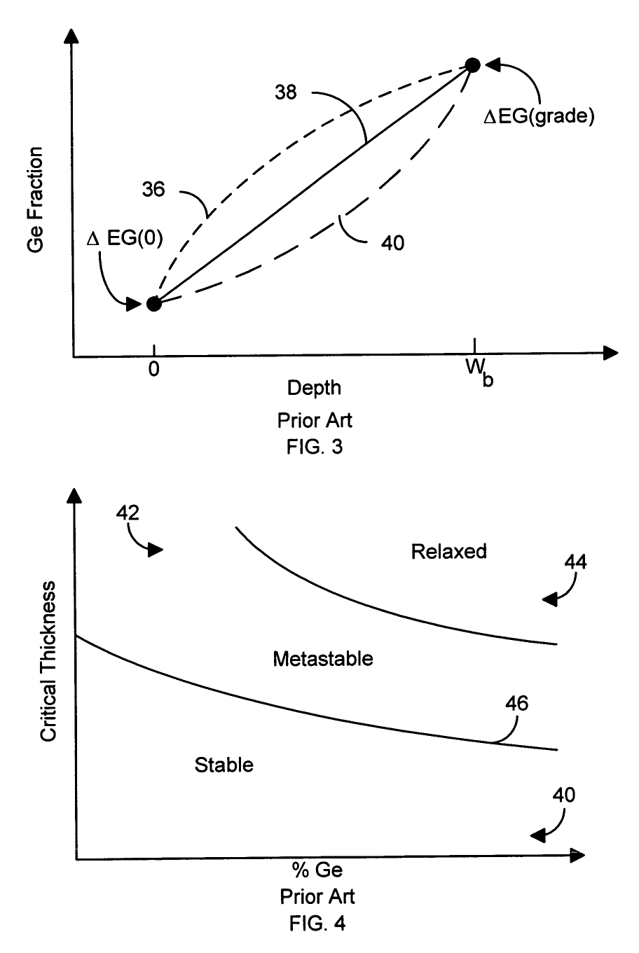

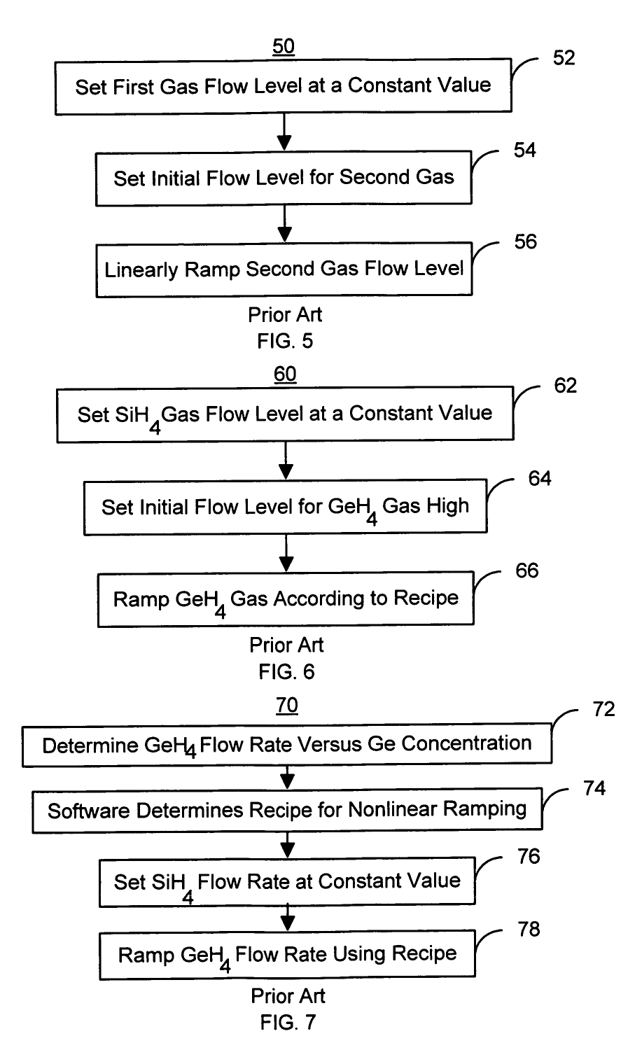

### DETAILED DESCRIPTION OF THE INVENTION

The present invention relates to semiconductor devices. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

A method and system for providing an alloy layer in a semiconductor device are described. The method and system ramping a first gas including a first constituent of the alloy layer from a first level to a second level different from the first level while the alloy layer is grown. The method and system also include ramping a second gas including a second constituent of the alloy layer from a third level to a fourth level different from the third level while the alloy layer is grown. In one aspect, the alloy layer includes silicon and germanium. In this aspect, the first gas includes silicon, while the second gas includes germanium.

The method and system will be described in terms of particular HBT devices. However, one of ordinary skill in the art will readily recognize that the method and system may be applicable to other device(s) having other, additional, and/or different components, dopants, and/or positions not inconsistent with the method and system. The method and system are also described in the context of particular methods. One of ordinary skill in the art will, however, recognize that the method could have other and/or additional steps. In addition, one of ordinary skill in the art will recognize that the methods may omit or combine steps for ease of explanation. Moreover, although the methods are described in the context of providing a single HBT device, one of ordinary skill in the art will readily recognize that multiple devices may be provided in parallel and/or series. The method and system are described in the context of providing a particular layer, a SiGe layer. However, one of ordinary skill in the art will recognize that the method and system may be used in connection with other alloy layers having additional and/or other constituents. The method and system are also described in the context of particular dopant profiles. However, one of ordinary skill in the art will readily recognize that the shapes, locations, and other features of the profiles may vary. The method and system are also described in the context of a two-constituent layer. However, one of ordinary skill in the art will recognize that the method and system may apply to layers having more constituents.

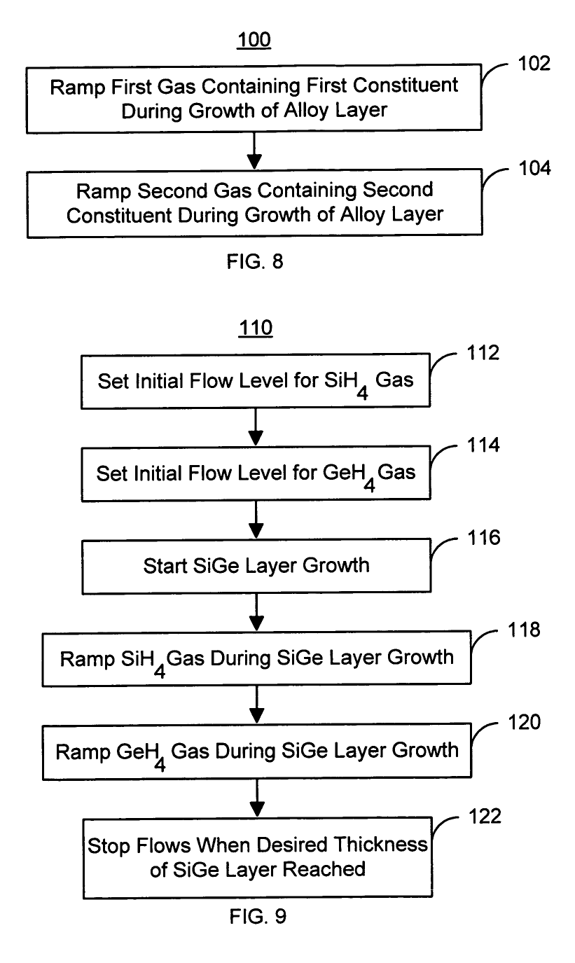

To more particularly illustrate the system and method, refer to FIG. 8 depicting one embodiment of a method 100 for providing an alloy layer having the desired profile in a semiconductor device. In a preferred embodiment, the alloy layer is a SiGe layer. However, in an alternate embodiment, an alloy layer having different and/or additional constituents may be used. In a preferred embodiment, the method 100 is used in growing the SiGe layer on an underlying Si layer. However, in an alternate embodiment, the alloy layer may reside on another layer. Thus, the method 100 may commence after formation of one or more layers on an underlying substrate or may be used to form the alloy layer directly on the substrate. The method preferably utilizes two gases to form the alloy layer. The first gas includes a first constituent of the layer, while the second gas includes a second alloy of the layer. The first gas including the first constituent of the alloy layer from a first level to a second level different from the first level while the alloy layer is grown, via step 102. In a preferred embodiment, the first gas is linearly ramped in step 102. Also in a preferred embodiment, the first and second levels are first and second flow rates, respectively. The second gas including the second constituent of the alloy layer from a third level to a fourth level different from the third level while the alloy layer is grown, via step 104. In a preferred embodiment, the second gas is linearly ramped in step 104. Also in a preferred embodiment, the third and fourth levels are third and fourth flow rates, respectively. The first, second, third, and fourth levels are selected based upon the desired profiles for the first and second constituents. In one embodiment, the first, second, third and fourth levels may be determined based upon a regression analysis performed on experimental data for the first and second gases. In a preferred embodiment, in which a SiGe layer is formed, the first gas is preferably SiH₄ and the second gas is preferably GeH₄. Also in a preferred embodiment, a SiGe layer having a concave profile is desired to be formed. Consequently, the SiH₄ gas is preferably ramped from a lower first flow rate to a higher second flow rate in step 102. Conversely, the GeH₄ gas is preferably ramped from a higher third flow rate to a lower fourth flow rate in step 104. Using the method 100, an alloy layer having the desired profiles for the constituents may be provided.

FIG. 9 is a flow chart depicting one embodiment of a method 110 for providing a SiGe layer having the desired Ge profile in a semiconductor device. In a preferred embodiment, the method 110 is used in growing the SiGe layer on an underlying Si layer. However, in an alternate embodiment, the alloy layer may reside on another layer. Thus, the method 110 may commence after formation of one or more layers on an underlying substrate or may be used to form the alloy layer directly on the substrate. The starting, or flow rate for the SiH₄ gas is set, via step 112. This flow rate is preferably low. The starting flow rate for GeH₄ gas is set, via step 114. This flow rate is preferably high. Growth of the SiGe film may then commence, via step 116. During growth of the SiGe film, the flow rate for the SiH₄ gas is ramped, via step 118. In a preferred embodiment, the flow rate for SiH₄ gas is ramped up (increased) during deposition. However, in another embodiment, the flow rate for SiH₄ gas may be ramped down in step 118. Also in a preferred embodiment, the ramp in step 118 is linear. During growth of the SiGe film, the flow rate for the GeH₄ gas is ramped, via step 120. In a preferred embodiment, the flow rate for GeSiH₄ gas is ramped down (decreased) during deposition. However, in another embodiment, the flow rate for GeH₄ gas may be ramped up in step 120. Also in a preferred embodiment, the ramp in step 120 is linear. Steps 118 and 120 preferably occur simultaneously. Thus, in a preferred embodiment, the flow rate for SiH₄ gas is decreased while the flow rate for GeH₄ gas is increased in order to obtain a particular Ge profile. However, in another embodiment, different ramps may be selected for different profiled. The flows may then be turned off when the desired thickness of SiGe is obtained, via step 122.

In the method 110, the flow rates chosen for SiH₄ gas and GeH₄ gas as well as the ramp selected determine the profile of the Ge within the SiGe layer. Although the flow rates for both SiH₄ gas and GeH₄ gas may be linearly ramped, a variety of Ge profiles including but not limited to concave profiles may be obtained. In one embodiment, experimental data can be obtained for the amount of Ge in a SiGe layer for particular flow rates of SiH₄ gas and GeH₄ gas. Regressions may be utilized to obtain the desired flow rates set in steps 112 and 114, the slopes of the ramps used in steps 118 and 120, as well as the final flow rates for the SiH₄ gas and GeH₄ gas when the flows are turned off in step 122 for the desired profile.

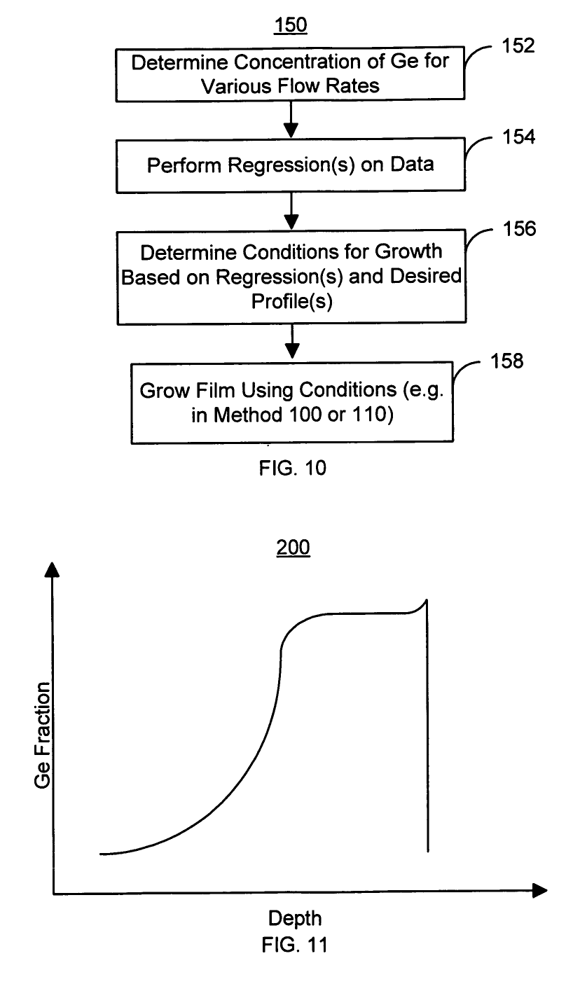

FIG. 10 is a flow chart depicting another embodiment of a method 150 for providing a SiGe layer having the desired Ge profile in a semiconductor device. In a preferred embodiment, the method 150 is used in growing the SiGe layer on an underlying Si layer. However, in an alternate embodiment, the alloy layer may reside on another layer. Experimental data is obtained on the amount of Ge in a SiGe layer for particular flow rates of SiH₄ gas and GeH₄ gas, via step 152. In one embodiment, step 152 could include populating a table of flow rates versus Ge concentration for different flow rates of SiH₄ gas and GeH₄ gas. Regressions may be performed to determine empirical relationships between the flow rates and Ge concentration, via step 154. Based on the regressions and the desired Ge profile, the starting flow rates, ending flow rates, and the slopes of the ramps, and other conditions used are determined, via step 156. The method 100 and/or 110 is then employed using the conditions selected in step 156, via step 158.

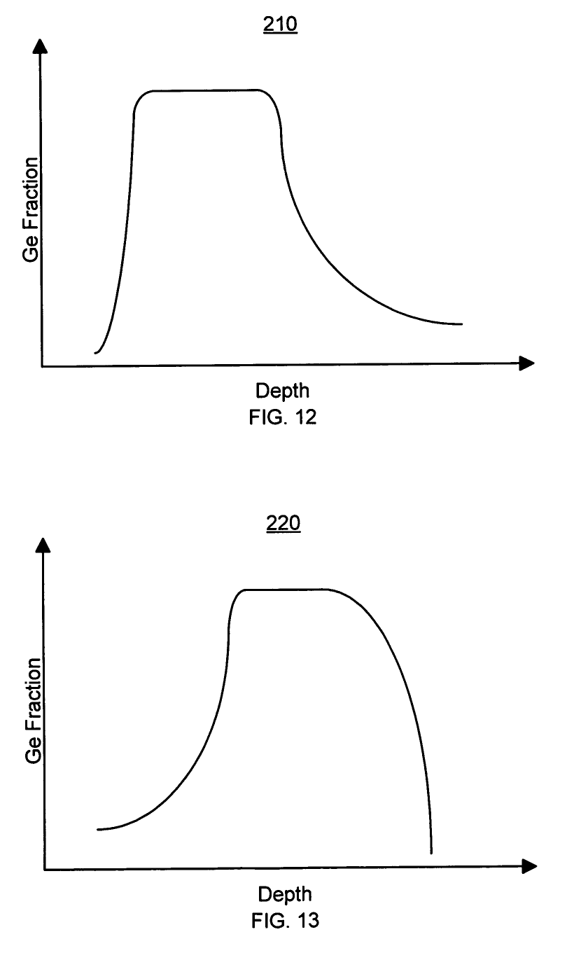

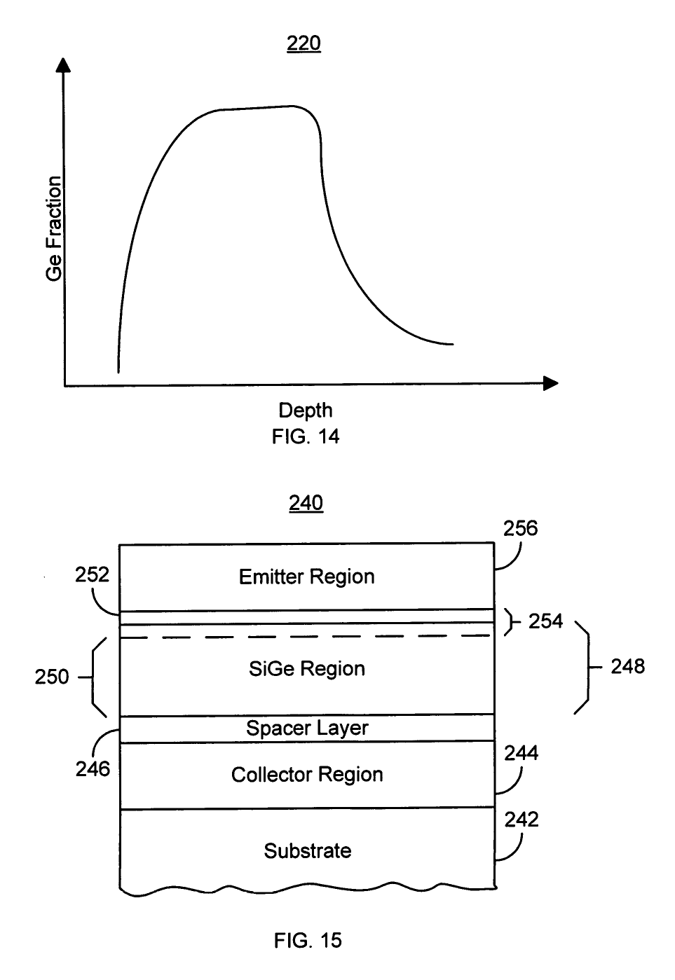

Using the method 100, 110, and/or 150, SiGe layer may have the desired energy band offsets ΔEG(grade) and ΔEG(0). Consequently, the desired built-in carrier drift E_{drift} and increased current, J_{c}, may be obtained. In addition, the desired Ge profile for the SiGe layer may be obtained. For example, FIGS. 11, 12, 13, and 14 depict embodiments of Ge profiles 200, 210, 220, and 230, respectively, using the method 100, 110, and/or 150. In one embodiment, a concave Ge profile may be obtained in the desired regions for the desired energy band offsets. Consequently, a lower amount of integrated Ge in the SiGe layer and, therefore, a lower strain may be achieved. For similar reasons, devices having a thickness greater than the critical thickness for SiGe may be obtained. Furthermore, the dopant diffusion and the final diffused dopant profiles, for example for B in the SiGe may be achieved. Thus, devices having narrow bases or shallower junctions may be provided. For example, FIG. 15 depicts one embodiment of a HBT device 240 in achieved using one embodiment of the method 100, 110, and/or 150. For clarity, FIG. 15 is not drawn to scale. The HBT device 240 includes a collector region 244 formed on a substrate 244, a spacer layer 246, a SiGe layer 248 grown in accordance with the method 100, 110, and/or 150, a cap region 254, and an emitter region 256. Because the profile of Ge in the SiGe layer may be tailored as desired using the method 100, 110, and/or 150, the SiGe may extend into the cap region 254. Thus, the base region 250 might occupy only a portion of the SiGe layer 248. Similarly, a portion of the cap region 254 is part of the SiGe layer 248 while a remaining portion 252 of the cap region 254 is outside of the SiGe layer. Such a device 240 may be less sensitive to thermal variations in processing. Consequently, device performance and yield may be enhanced. Thus, using the method 100, 110, and/or 150, the desired SiGe layer having the desired Ge profile may be formed. Thus, the method 100, 110, and/or 150 may provide SiGe devices, such as an HBT device, that desired energy band offsets but is less susceptible to complete film relaxation without requiring specialized equipment. Consequently, improved performance, yield, and reliability may be achieved.

A method and system for providing an alloy layer in a semiconductor device has been disclosed. The present invention has been described in accordance with the embodiments shown, and one of ordinary skill in the art will readily recognize that there could be variations to the embodiments, and any variations would be within the spirit and scope of the present invention. Accordingly, many modifications may be made by one of ordinary skill in the art without departing from the spirit and scope of the appended claims.

What is claimed is:

1. A method for providing an alloy layer in semiconductor device comprising:
ramping a first gas including a first constituent of the alloy layer from a first level to a second level different from the first level while the alloy layer is grown;
ramping a second gas including a second constituent of the alloy layer from a third level to a fourth level different from the third level while the alloy layer is grown.

2. The method of claim 1 wherein the first level is higher than the second level and the fourth level is higher than the third level.

3. A method for providing a layer including silicon and germanium in semiconductor device comprising:
ramping a first gas including the silicon from a first level to a second level different from the first level while the layer is grown, the first level being lower than the second level;
ramping a second gas including the germanium from a third level to a fourth level different from the third level while the layer is grown, the third level being higher than the fourth level.

4. The method of claim 3 wherein the first gas ramping further includes:
linearly ramping the first gas from the first level to the second level.

5. The method of claim 3 wherein the first gas ramping further includes:
linearly ramping the second gas from the third level to the fourth level.

6. The method of claim 3 wherein the layer has a thickness greater than a critical thickness of SiGe on a silicon substrate.

7. The method of claim 3 wherein the ramping the first gas and the ramping the second gas further include including the silicon of the layer from a first level to a second level different from the first level while the layer is grown, the first level being lower than the second level;
selecting the first level, the second level, the third level, and the fourth level such that the germanium has a concave profile in the layer.

8. The method of claim 3 wherein the first level includes a first flow rate, the second level includes a second flow rate, the third level includes a third flow rate, and the fourth level includes a fourth flow rate.

9. The method of claim 3 wherein the first gas is SiH₄ and the second gas is GeH₄.

10. The method of claim 3 wherein the first level, the second level, the third level and the fourth level are determined based upon at least one regression analysis.

11. A method for providing a SiGe layer in semiconductor device comprising:
linearly ramping a first gas including silicon from a first flow rate to a second flow rate different from the first flow rate while the SiGe layer is grown, the first flow rate being lower than the second flow rate;
linearly ramping a second gas including germanium from a third flow rate to a fourth flow rate different from the third flow rate while the SiGe layer is grown, the third flow rate being higher than the fourth flow rate;
wherein the first flow rate, the second flow rate, the third flow rate and the fourth flow rate are selected such that the SiGe layer has a concave germanium profile and such that the SiGe layer has a thickness greater than a critical thickness for SiGe.

12. The method of claim 11 wherein the first flow rate, the second flow rate, the third flow rate and the fourth flow rate are determined based upon at least one regression analysis.

13. A semiconductor device comprising:
a layer including an alloy of a first constituent and a second constituent, the layer being formed by ramping a first gas including a first constituent of the layer from a first level to a second level different from the first level and ramping a second gas including a second constituent of the layer from a third level to a fourth level different from the third level while the layer is grown.

14. A bipolar transistor comprising:
a silicon-germanium layer, the silicon-germanium layer being formed by ramping a first gas including a silicon from a first level to a second level different from the first level and ramping a second gas including germanium from a third level to a fourth level different from the third level while the layer is grown, at least a portion of the silicon-germanium layer including a compound base region and at least a portion of an emitter cap region;
an emitter region coupled with the compound base region, the emitter cap region residing between the emitter region and the compound base region; and
a collector region coupled with the compound base region.

15. The bipolar transistor of claim 14 wherein the silicon-germanium layer has a thickness greater than a critical thickness of SiGe on a silicon substrate.

16. The bipolar transistor of claim 14 wherein the germanium has a concave profile in the layer.

17. The bipolar transistor of claim 14 wherein the first gas is SiH₄ and the second gas is GeH₄.

18. The bipolar transistor of claim 14 wherein the first level, the second level, the third level and the fourth level are determined based upon at least one regression analysis.
